(19) United States
(12) Patent Application Publication
(10) Pub. No.: US 2017/0098599 A1
(43) Pub. Date: Apr. 6, 2017

(54) OXIDE SEMICONDUCTOR DEVICE AND MANUFACTURING METHOD THEREOF

(71) Applicant: United Microelectronics Corp., Hsin-Chu City (TW)

(72) Inventors: ZHIBIAO ZHOU, Singapore (SG); Shao-Hui Wu, Singapore (SG); Chi-Fa Ku, Kaohsiung City (TW); Chen-Bin Lin, Taipei City (TW)

(21) Appl. No.: 14/873,189

(22) Filed: Oct. 1, 2015

(51) Int. Cl. H01L 23/498; H01L 27/108; H01L 27/115; H01L 29/66; H01L 27/12; H01L 21/48; H01L 29/786

(52) U.S. Cl. CPC H01L 23/49827; H01L 21/486; H01L 27/10805; H01L 27/1085; H01L 27/10873; H01L 29/7869; H01L 29/66969; H01L 27/1218; H01L 27/1255; H01L 27/124; H01L 27/1259; H01L 27/115

(57) ABSTRACT

A manufacturing method of an oxide semiconductor device includes the following steps. An interposer substrate is provided. At least one oxide semiconductor transistor is formed on the interposer substrate. At least one trough silicon via (TSV) is formed in the interposer substrate. An interconnection structure on the interposer substrate, and the at least one oxide semiconductor transistor is connected to the interconnection structure.

### BACKGROUND OF THE INVENTION

1. Field of the Invention

The present invention relates to an oxide semiconductor device and a manufacturing method thereof, and more particularly, to an oxide semiconductor device including at least one oxide semiconductor transistor formed on an interposer substrate and at least one trough silicon via (TSV) formed in the interposer substrate and a manufacturing method thereof.

2. Description of the Prior Art

There are many different kinds of electronic products in the market, and no matter how inventive the functions of these products are or how the functions vary, power consumption is always an important subject to be improved in all kinds of the electronic products. For portable electronic products such as smart phones, smart watches, and electronic bracelets, compact and lightweight designs and battery life are important specifications of the products. For enhancing the battery life without affecting the compact and lightweight designs, improving the power consumption of the electronic device is the most basic and direct approach. For the purpose of power consumption, oxide semiconductor materials such as indium gallium zinc oxide (IGZO) are applied in field effect transistors (FETs) of integrated circuits because of the properties of low leakage current and high mobility.

### SUMMARY OF THE INVENTION

According to the claimed invention, a manufacturing method of an oxide semiconductor device is provided. The manufacturing method includes the following steps. An interposer substrate is provided. At least one oxide semiconductor transistor is formed on the interposer substrate. At least one trough silicon via (TSV) is formed in the interposer substrate. An interconnection structure on the interposer substrate, and the at least one oxide semiconductor transistor is connected to the interconnection structure.

According to the claimed invention, an oxide semiconductor device is provided. The oxide semiconductor device includes an interposer substrate, at least one trough silicon via (TSV) , at least one oxide semiconductor transistor, a first interlayer dielectric, an interconnection structure, and a capacitor structure. At least a part of the TSV is disposed in the interposer substrate. The oxide semiconductor transistor is disposed on the interposer substrate. The first interlayer dielectric is disposed on the interposer substrate, and the oxide semiconductor transistor is disposed between the first interlayer dielectric and the interposer substrate. The interconnection structure is disposed on the first interlayer dielectric. The oxide semiconductor transistor is connected to the interconnection structure, and the TSV penetrates the interposer substrate and the first interlayer dielectric for being connected to the interconnection structure. The capacitor structure is disposed on the interposer substrate. The capacitor structure is connected to the oxide semiconductor transistor for forming an oxide semiconductor memory cell. The capacitor structure includes a first conductive pattern, a dielectric pattern, and a second conductive pattern. The dielectric pattern is disposed on the first conductive pattern, and the second conductive pattern is disposed on the dielectric pattern.

According to the oxide semiconductor device and the manufacturing method thereof in the present invention, the oxide semiconductor transistor is integrated with the interposer substrate having the TSV. The process sequence of the oxide semiconductor transistor, the TSV, and the interconnection structure is modified for different considerations. The capacitor structure connected to the oxide semiconductor transistor is also integrated with the interposer substrate having the TSV for forming the oxide semiconductor memory cell with relatively longer data retention performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a manufacturing method of an oxide semiconductor device according to a first embodiment of the present invention.

FIG. 2 is a schematic drawing illustrating the manufacturing method of the oxide semiconductor device according to the first embodiment of the present invention.

FIG. 3 is a schematic drawing illustrating an oxide semiconductor memory cell according to the first embodiment of the present invention.

FIG. 4 is a schematic drawing illustrating a memory array according to the first embodiment of the present invention.

FIG. 5 is a schematic drawing illustrating the oxide semiconductor device according to the first embodiment of the present invention.

FIG. 6 is a schematic drawing illustrating a capacitor structure according to another embodiment of the present invention.

FIG. 7 is a schematic drawing illustrating a top view of a capacitor structure having a circle shaped capacitor trench.

FIG. 8 is a schematic drawing illustrating a top view of a capacitor structure having a cross shaped capacitor trench.

FIG. 9 is a schematic drawing illustrating a top view of a capacitor structure having a rectangle shaped capacitor trench.

FIG. 10 is a schematic drawing illustrating a top view of a capacitor structure having two circle shaped capacitor trenches.

FIG. 11 is a schematic drawing illustrating a capacitor structure according to further another embodiment of the present invention.

FIG. 12 is a flow chart of a manufacturing method of an oxide semiconductor device according to a second embodiment of the present invention.

FIG. 13 is a schematic drawing illustrating the oxide semiconductor device according to the second embodiment of the present invention.

FIG. 14 is a flow chart of a manufacturing method of an oxide semiconductor device according to a third embodiment of the present invention.

FIG. 15 is a schematic drawing illustrating the oxide semiconductor device according to the third embodiment of the present invention.

### DETAILED DESCRIPTION

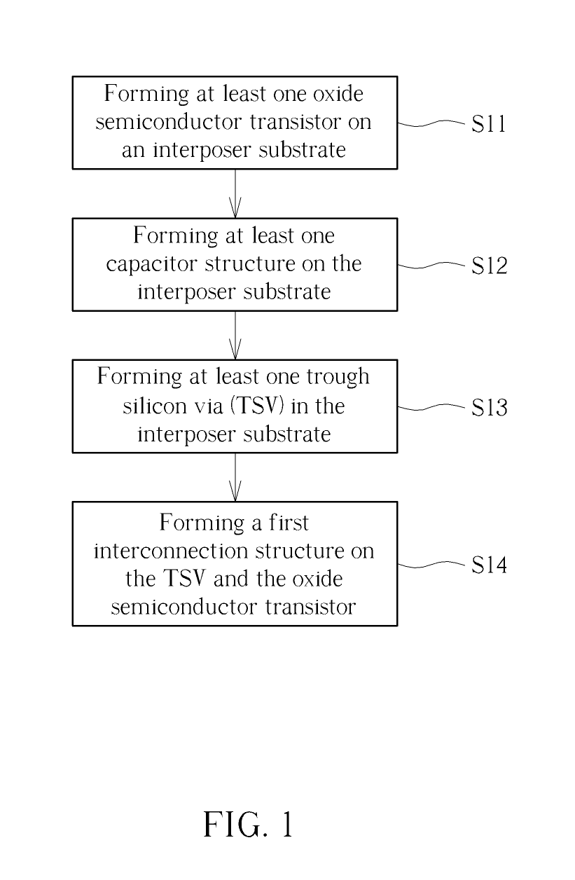

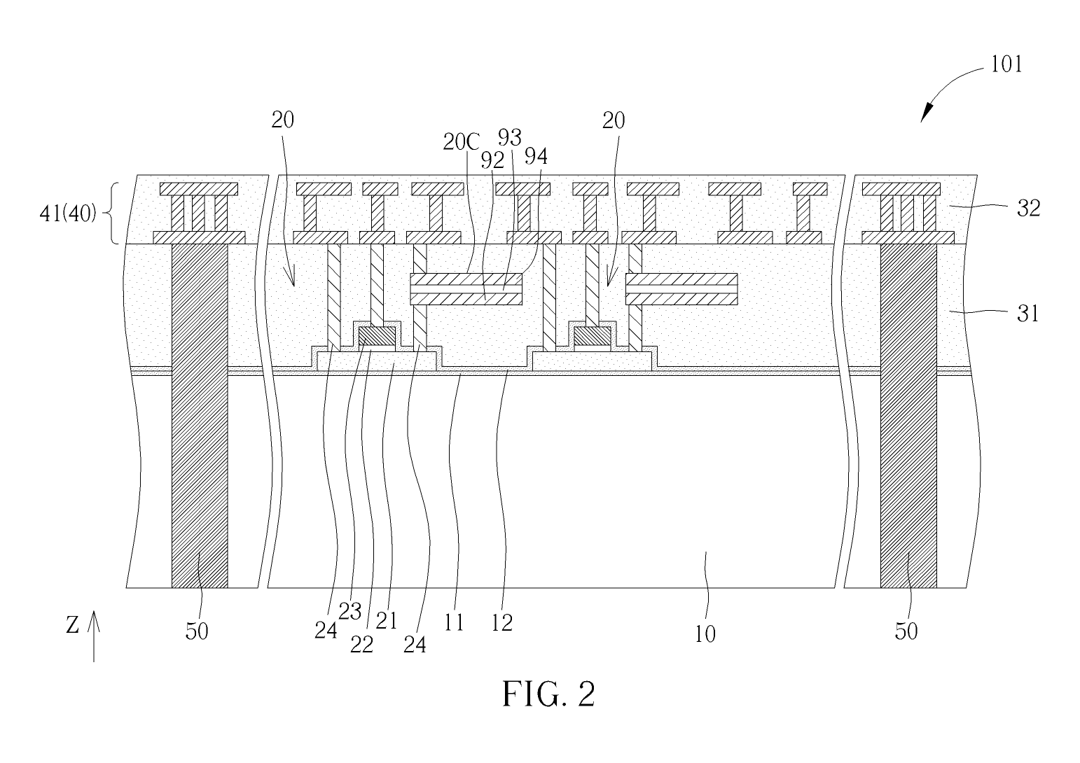

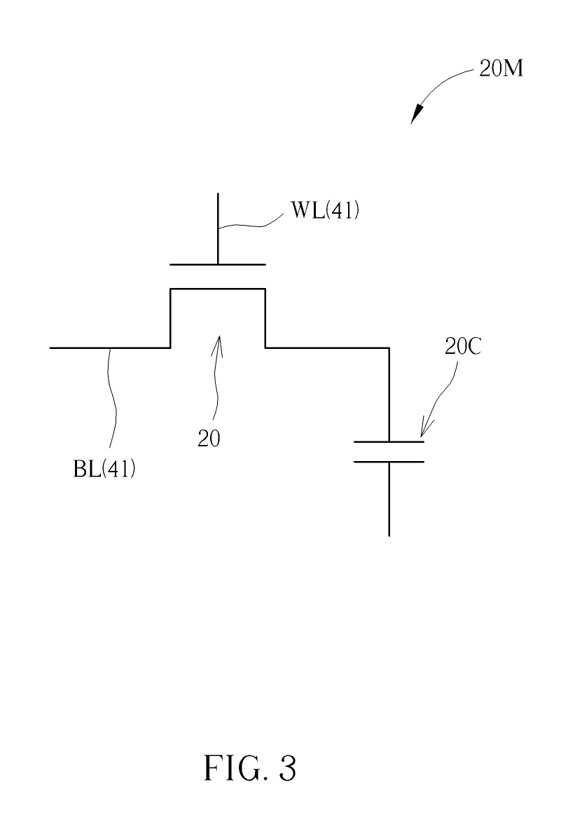

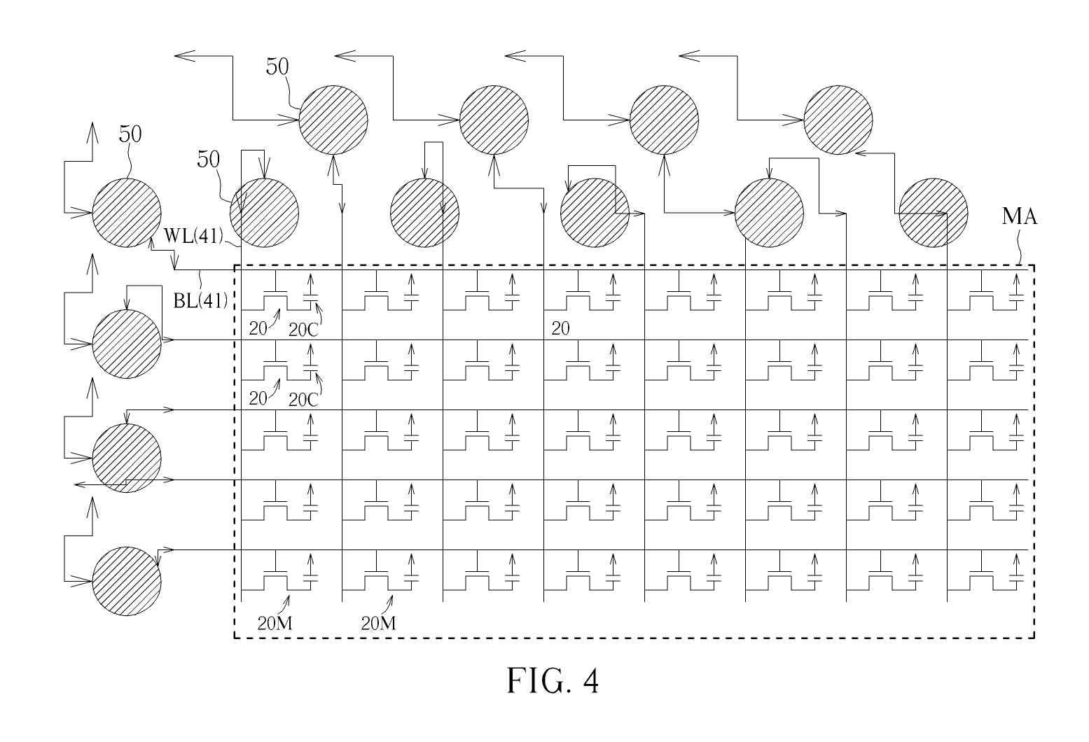

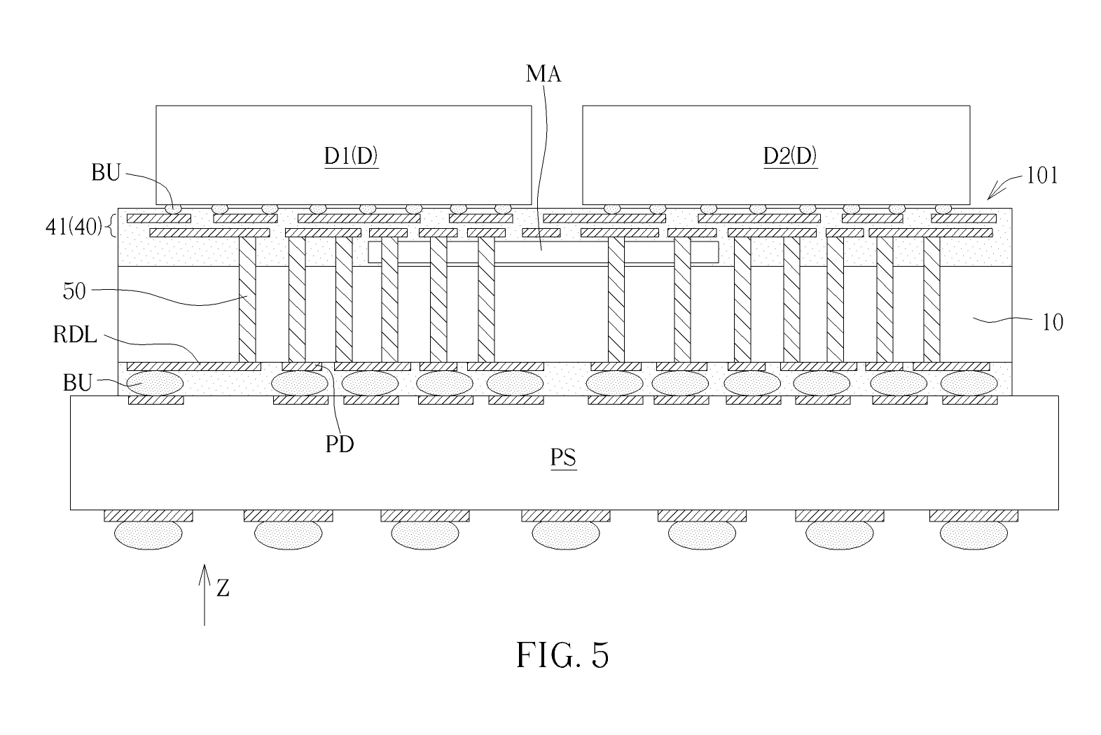

Please refer to FIGS. 1-5. FIG. 1 is a flow chart of a manufacturing method of an oxide semiconductor device according to a first embodiment of the present invention. FIG. 2 is a schematic drawing illustrating the manufacturing method of the oxide semiconductor device in this embodiment. FIG. 3 is a schematic drawing illustrating an oxide semiconductor memory cell in this embodiment. FIG. 4 is a schematic drawing illustrating a memory array in this embodiment. FIG. 5 is a schematic drawing illustrating the oxide semiconductor device in this embodiment. As shown in FIG. 1 and FIG. 2, the manufacturing method of the oxide semiconductor device in this embodiment includes the following steps. In step S11, an interposer substrate 10 is provided, and at least one oxide semiconductor transistor 20 is formed on the interposer substrate 10. The interposer substrate 10 maybe an electrical interface routing between different dies and a package substrate, and the interposer substrate 10 may be used to spread a connection to a wider pitch or to reroute a connection to a different connection. There is not any silicon based metal-oxide-semiconductor (MOS) device disposed in and/or on the interposer substrate 10 preferably. The oxide semiconductor transistor 20 may include an oxide semiconductor layer 21, a gate dielectric layer 22, a gate electrode 23, and a pair of source/drain electrodes 24. The oxide semiconductor layer 21 may include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO₂), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned materials, but not limited thereto.

In this embodiment, the oxide semiconductor transistor 20 may be a top gate transistor, but the present invention is not limited to this. In other embodiments of the present invention, other structures such as a bottom gate transistor or a dual gate transistor may also be applied. In this embodiment, the manufacturing process of some parts in the oxide semiconductor transistor 20, such as the gate electrode 23 and the source/drain electrodes 24, may be integrated with the manufacturing process of the interconnection preferably, but not limited thereto. The interposer substrate 10 in this embodiment may include a silicon substrate preferably, but not limited thereto. Other suitable substrates such as a glass substrate may also be applied as the interposer substrate. Additionally, a first barrier layer 11 maybe optionally formed on the interposer substrate 10 before the step of forming the oxide semiconductor layer 21, and a second barrier layer 12 may be optionally formed on the oxide semiconductor layer 21. The oxide semiconductor transistor 20 may be sealed by the first barrier layer 11 and the second barrier layer for avoiding ambient influence.

In step S12, a capacitor structure 20C may be selectively formed on the interposer substrate 10, and the capacitor structure 20C may be connected to the oxide semiconductor transistor 20 for forming an oxide semiconductor memory cell 20M shown in FIG. 3. The capacitor structure 20C may include a stacked metal-insulator-metal (MIM) structure or other suitable structures. For example, the capacitor structure 20C may include a first conductive pattern 92, a dielectric pattern 93, and a second conductive pattern 92 stacked in a vertical direction Z. Additionally, a first interlayer dielectric 31 may be formed on the interposer substrate 10 and cover the oxide semiconductor transistor 20. The first interlayer dielectric 31 may include a plurality of dielectric layers (not shown in FIG. 2) stacked in the vertical direction Z, and the capacitor structure 20C may be disposed in the first interlayer dielectric 31. The material of the first interlayer dielectric 31 may include silicon nitride, silicon oxide, silicon oxynitride, or other suitable dielectric materials.

In step S13, at least one trough silicon via (TSV) 50 may be formed in the interposer substrate 10. The TSV 50 in this embodiment may penetrate the interposer layer 10, the first barrier layer 11, the second barrier layer 12, and the first interlayer dielectric 31 in the vertical direction Z. The TSV may include a main conductive material (not shown) and an insulating barrier layer (not shown) surrounding the main conductive material, but not limited thereto. Subsequently, in step S14, an interconnection structure 40 may be formed on the interposer substrate 10. More specifically, the interconnection structure 40 may include a first interconnection 41, the first interconnection 41 and a second interlayer dielectric 32 maybe formed on the first interlayer dielectric 31 in this embodiment, and at least a part of the first interconnection 41 is formed in the second interlayer dielectric 32. The oxide semiconductor transistor 20 is connected to the interconnection structure 40. The TSV 50 may be also connected to a part of the interconnection structure 40, and the oxide semiconductor transistor 20 may be electrically connected to the TSV 50 through the interconnection structure 40 accordingly.

In the manufacturing method of this embodiment, the TSV 50 is formed after the step of forming the oxide semiconductor transistor 20, and the interconnection structure 40 is formed after the step of forming the TSV 50. The TSV 50 may be formed after the step of forming the oxide semiconductor transistor 20 because there is no stress and contamination concern for the oxide semiconductor transistor 20 in the process of forming the TSV 50. In addition, high temperature processes may also be applied before the step of forming the TSV 50. An oxide semiconductor device 101 shown in FIG. 2 may be obtained by the manufacturing method described above.

As shown in FIGS. 2-4, the oxide semiconductor device 101 includes the interposer substrate 10, at least one TSV 50, at least one oxide semiconductor transistor 20, the first interlayer dielectric 31, the interconnection structure 40, and the capacitor structure 20C. At least a part of the TSV 50 is disposed in the interposer substrate 10. The oxide semiconductor transistor 20 is disposed on the interposer substrate 10. The first interlayer dielectric 31 is disposed on the interposer substrate 10, and the oxide semiconductor transistor 20 is disposed between the first interlayer dielectric 31 and the interposer substrate 10. The interconnection structure 40 is disposed on the first interlayer dielectric 31. The oxide semiconductor transistor 20 is connected to the interconnection structure 40, and the TSV 50 penetrates the interposer substrate 10 and the first interlayer dielectric 31 for being connected to the interconnection structure 40. The capacitor structure 20C is disposed on the interposer substrate 10. The capacitor structure 20C is connected to the oxide semiconductor transistor 20 for forming an oxide semiconductor memory cell 20M. In other words, the oxide semiconductor memory cell 20M is composed of the oxide semiconductor transistor 20 and the capacitor structure 20C. The capacitor structure 20C includes the first conductive pattern 92, the dielectric pattern 93, and the second conductive pattern 94. The dielectric pattern 93 is disposed on the first conductive pattern 92, and the second conductive pattern 94 is disposed on the dielectric pattern 93. A memory array MA composed of a plurality of the oxide semiconductor memory cells 20M may be disposed on the interposer substrate 10. In this embodiment, the first interconnection 41 may include a plurality of words lines WL and a plurality of bit lines BL connected to the oxide semiconductor memory cells 20M in the memory array MA, and the word lines WL and the bit lines BL may be electrically connected to the TSVs 50 respectively.

As shown in FIG. 5, the manufacturing method in this embodiment may further include forming a plurality of connection pads PD and at least one redistribution layer RDL corresponding to the TSVs 50, and forming a plurality of conductive bumps BU on the first interconnection 41, the connection pads PD, and the redistribution layer RDL. At least one die D may be attached to the interconnection structure 40 and electrically connected to the interconnection structure 40 through the conductive bumps BU. The oxide semiconductor transistor 20 maybe electrically connected to the die D through the TSV 50 and/or the interconnection structure 40. More specifically, there maybe a plurality of dies D (such as a first die D1 and a second die D2 shown in FIG. 5) attached to the interconnection structure 40. The first die D1, the second die D2, and the interposer substrate 10 may be disposed on a package substrate PS, and the TSVs 50 may be electrically connected to the package substrate PS through the connection pads PD and the conductive bumps BU. Accordingly, the memory array MA may also be electrically connected to the package substrate PS and other dies connected to the package substrate PS. Electrical components related to the memory array MA, such as signal analyzers, driver IC, or a I/O controller, may be disposed in the dies D and/or the dies connected to the package substrate PS, and the memory array MA may be electrically connected to the related electrical components though the TSVs 50 and/or the interconnection structure 40. In other words, the oxide semiconductor device 101 may further include the dies D and the package substrate PS described above. The die D may be disposed on the interconnection structure 40, and the oxide semiconductor transistor 20 may be electrically connected to the die D through the TSV 50 and/or the interconnection structure 40. Therefore, the oxide semiconductor device 101 in this embodiment may also be regarded as a 2.5D IC package structure, but not limited thereto. In the oxide semiconductor device 101 of this embodiment, the memory array MA composed of oxide semiconductor transistors 20 is integrated in the interposer substrate 10 having the TSVs 50, and the oxide semiconductor transistors 20 may be electrically connected to other electrical components, such as signal analyzers, driver IC, or a I/O controller, through the TSVs 50 integrated in the interposer substrate 10. The data retention performance of the memory array MA may be enhanced because of the ultra-low leakage current property of the oxide semiconductor transistors 20. The power consumption of the oxide semiconductor device 101 will be relatively low and may be applied to save power in active modes and standby modes.

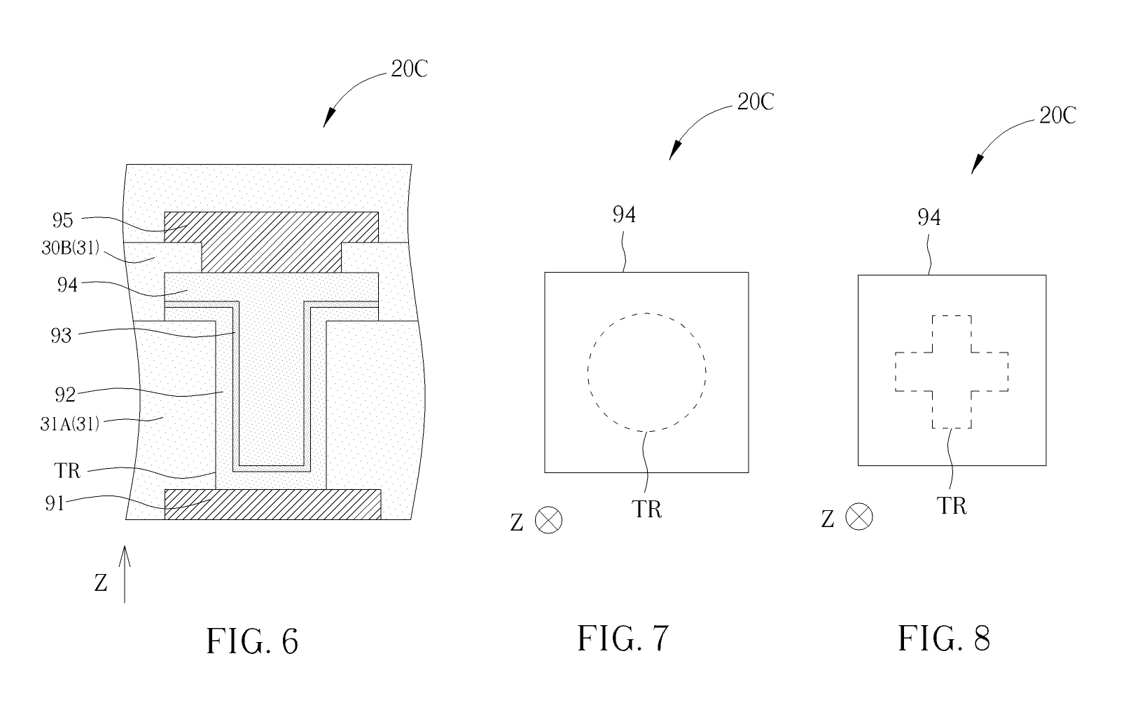

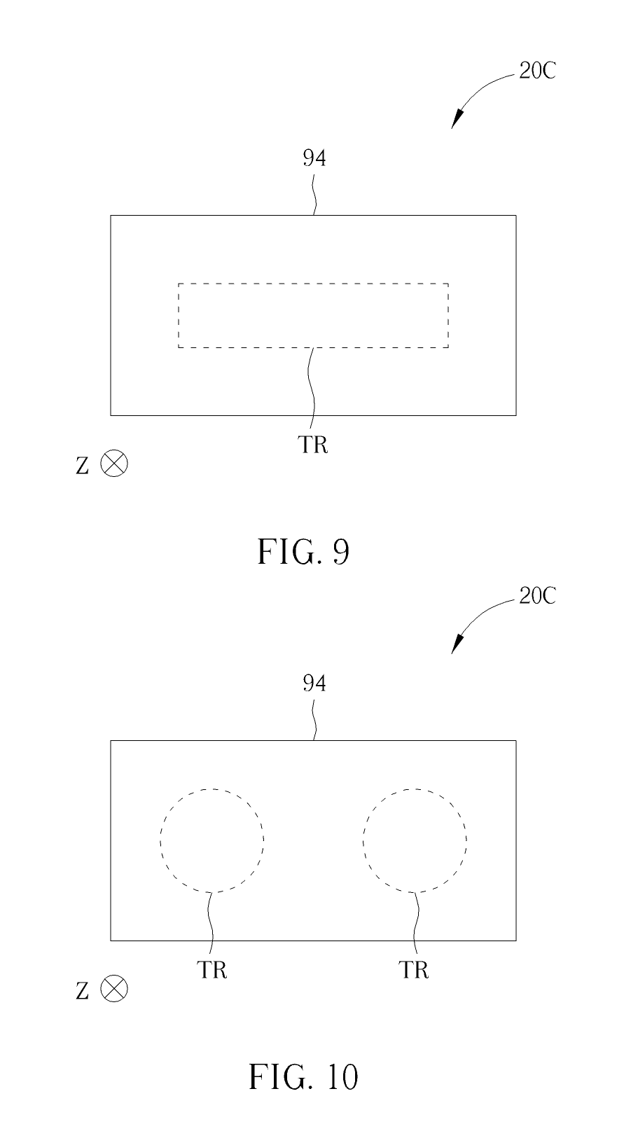

Please refer to FIGS. 6-10. FIG. 6 is a schematic drawing illustrating a capacitor structure according to another embodiment of the present invention. FIGS. 7-10 are schematic drawings illustrating the capacitor trenches in different shapes. As shown in FIG. 6, the oxide semiconductor device may further include at least one capacitor trench TR disposed in the first interlayer dielectric 31. At least a part of the capacitor structure 20C is disposed in the capacitor trench TR, and the capacitor trench TR is filled with the first conductive pattern 92, the dielectric pattern 93, and the second conductive pattern 94. More specifically, the first conductive pattern 92 and the dielectric pattern 93 are conformally disposed in the capacitor trench TR preferably, and the second conductive pattern 94 may have superior gap-filling ability for forming on the dielectric pattern 93 and filling the capacitor trench TR. The dielectric pattern 93 may include silicon oxide, silicon nitride, silicon oxynitride, an oxide-nitride-oxide (ONO) structure, aluminum oxide (Al₂O₃), hafnium oxide (HfOₓ), zirconium oxide (ZrOₓ), barium titanate (BaTiOₓ), or other suitable dielectric materials. The capacitor structure 20C in this embodiment may be regarded as a 3D capacitor structure because the first conductive pattern 92, the dielectric pattern 93, and the second conductive pattern 94 are stacked in both the vertical direction Z and the horizontal direction for increasing the capacitance within limited area in the vertical direction Z. The size of the memory cell and the size of the memory array may be reduced accordingly.

In this embodiment, the first interlayer dielectric 31 may include a first dielectric layer 31A and a second dielectric layer 31B stacked in the vertical direction Z. The second dielectric layer 31B is disposed on and directly contacts the first dielectric layer 31A, and the capacitor trench TR penetrates the first dielectric layer 31A. The first conductive pattern 92, the dielectric pattern 93, and the second conductive pattern 94 may be partially disposed between the first dielectric layer 31A and the second dielectric layer 31B in the vertical direction Z. The capacitor structure 20C may further include a bottom electrode 91 and a top electrode 95 optionally. The bottom electrode 91 and the top electrode 95 may be connected to the first conductive pattern 92 and the second conductive pattern 93 respectively, and at least one of the bottom electrode 91 or the top electrode is electrically connected to the oxide semiconductor transistor described above. In this embodiment, the manufacturing process of some parts in the capacitor structure 20C, such as the bottom electrode 91 and the top electrode 95, may be integrated with the manufacturing process of the interconnection in the first interlayer dielectric 31 preferably, but not limited thereto.

As shown in FIGS. 7-10, from a top view of the capacitor structure 20C, the shape of the capacitor trench TR may include a circle, a cross, a rectangle, or other suitable shapes for the concern about increasing the capacitance of the capacitor structure 20C. In additionally, the capacitor structure 20C may have more than one capacitor trench TR for further increasing the capacitance of each capacitor structure 20C, and the capacitor trenches TR may have different shapes described above respectively.

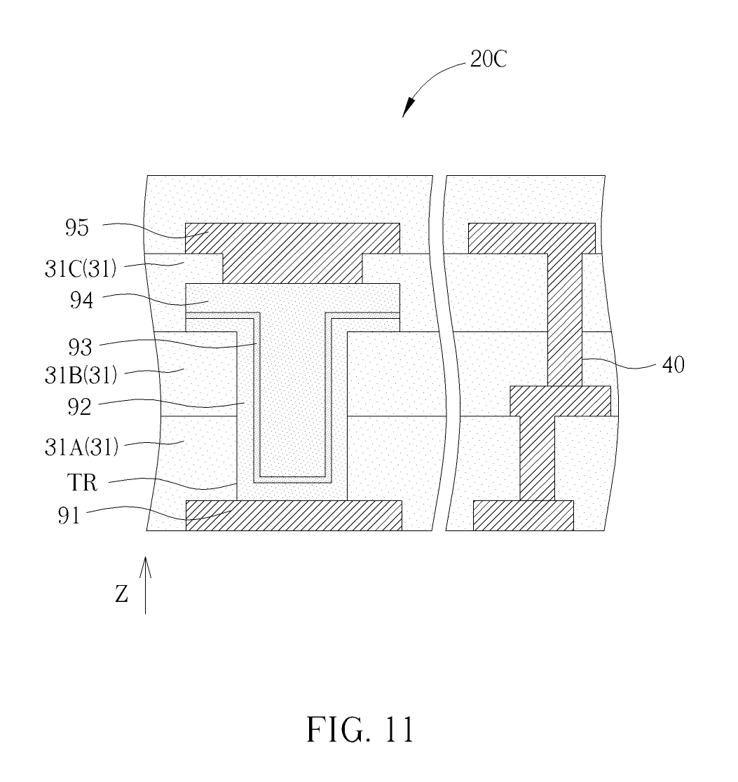

Please refer to FIG. 11. FIG. 11 is a schematic drawing illustrating a capacitor structure according to further another embodiment of the present invention. In this embodiment, the first interlayer dielectric 31 may further include a third dielectric layer 31C disposed on the second dielectric layer 31B. The capacitor trench TR may penetrate the first dielectric layer 31A and the second dielectric layer 31B. The first conductive pattern 92, the dielectric pattern 93, and the second conductive pattern 94 may be partially disposed between the second dielectric layer 31B and the third dielectric layer 31C in the vertical direction Z. The manufacturing process of the bottom electrode 91 and the top electrode 95 may also be integrated with the manufacturing process of the interconnection structure 40 in the first interlayer dielectric 31 preferably, but not limited thereto. In other words, the capacitor trench TR may penetrate more than one of the dielectric layers in the first interlayer dielectric 31 for increasing the depth of the capacitor trench TR, and the capacitance of the capacitor structure 20C may be increased accordingly. It is worth noting that the capacitor structures in different shapes described above may also be applied in other embodiments in the present invention, such as the embodiments to be described below.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

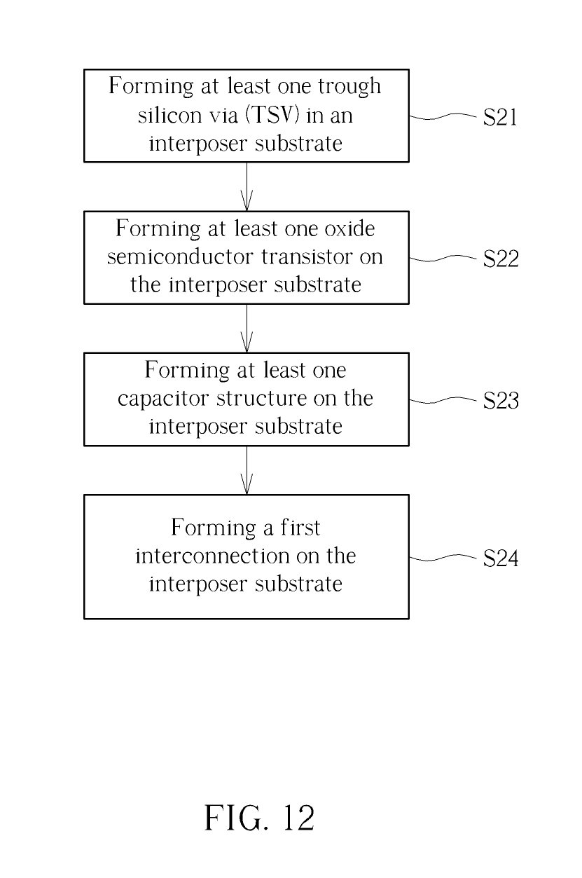

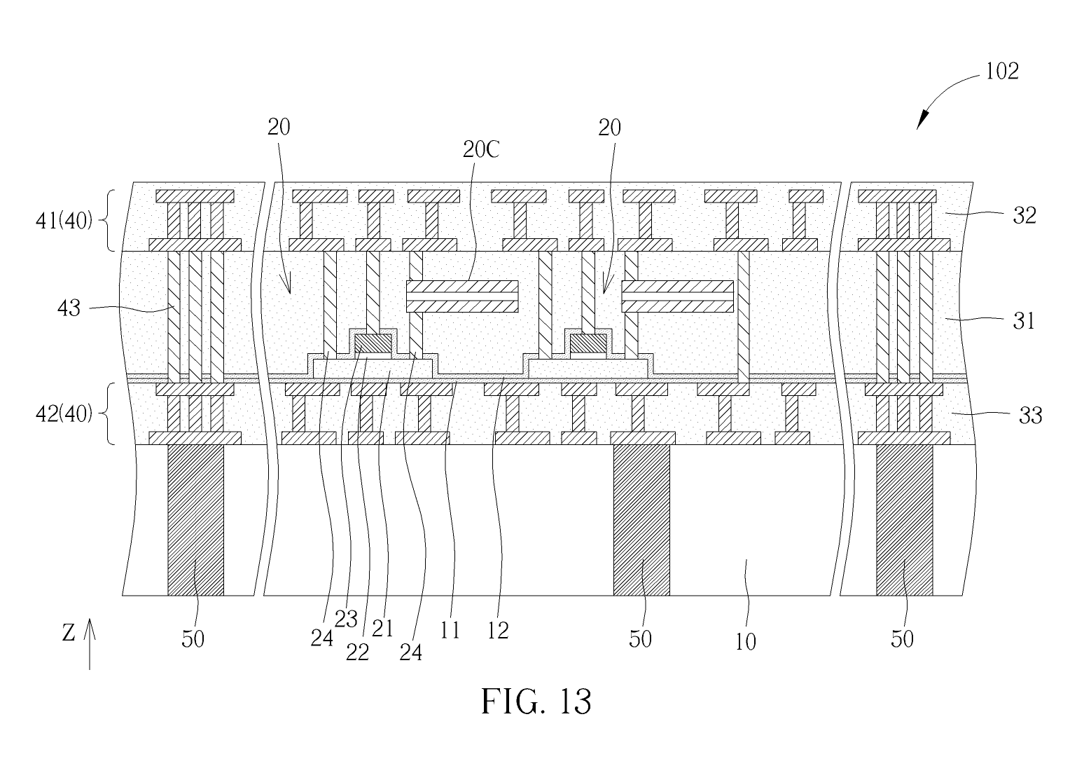

Please refer to FIG. 12 and FIG. 13. FIG. 12 is a flow chart of a manufacturing method of an oxide semiconductor device 102 according to a second embodiment of the present invention. FIG. 13 is a schematic drawing illustrating the oxide semiconductor device 102 in this embodiment. As shown in FIG. 12 and FIG. 13, the TSV 50 is formed in the interposer substrate 10 in step S21; the oxide semiconductor transistor 20 is then formed on the interposer substrate 10 in step S22; the capacitor structure 20C is formed on the interposer substrate 10 in step S23; and the first interconnection 41 is formed on the interposer substrate 10 in step S24. In other words, the TSV 50 in this embodiment is formed before the step of forming the oxide semiconductor transistor 20, and the process of forming the TSV 50 will not influence the oxide semiconductor transistor 20 accordingly. In addition, the interconnection structure 40 in this embodiment may include the first interconnection 41 and a second interconnection 42. The second interconnection 42 is formed on the interposer substrate 10 before the step of forming the oxide semiconductor transistor 20 and after the step of forming the TSV 50. The first interconnection 41 is formed after the step of forming the oxide semiconductor transistor 20. A third interconnection 43 maybe formed in the first interlayer dielectric 31 for connecting the first interconnection 41 and the second interconnection 42. The oxide semiconductor transistor 20 maybe electrically connected to the TSV through the first interconnection 41 and/or the second interconnection 42.

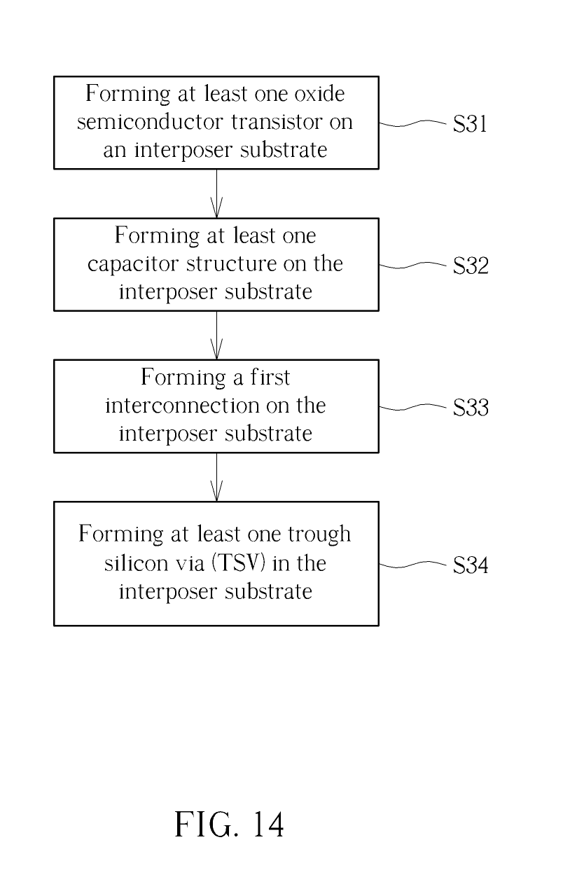

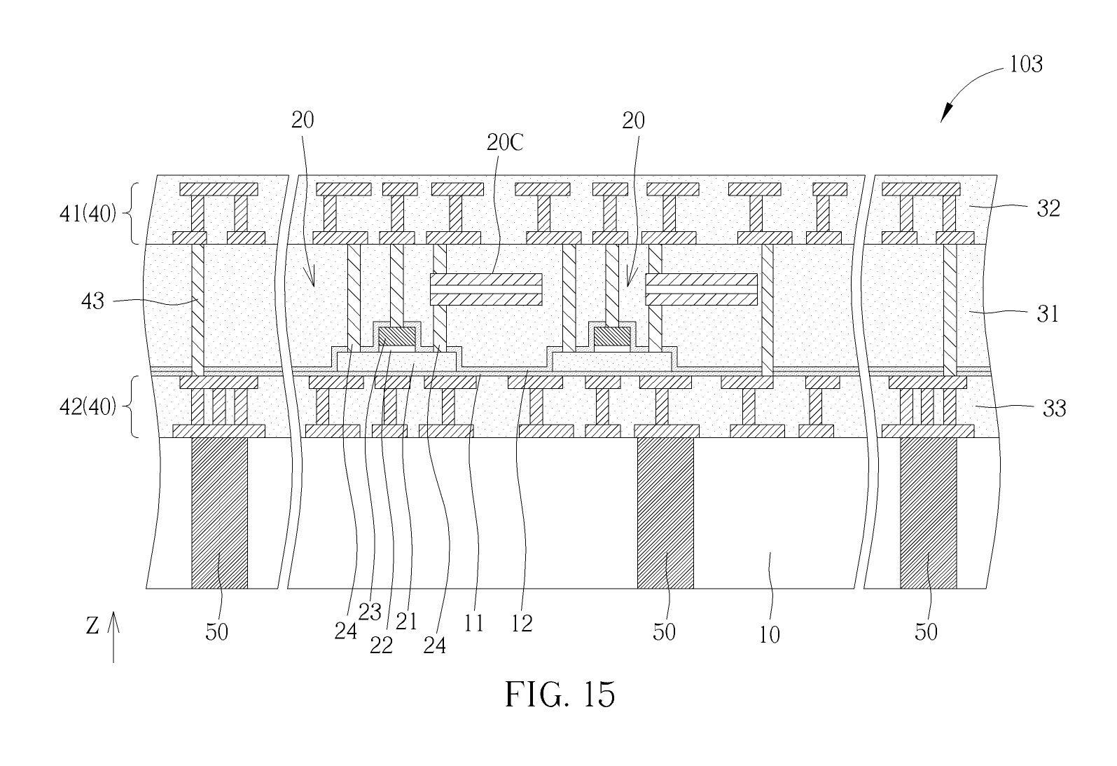

Please refer to FIG. 14 and FIG. 15. FIG. 14 is a flow chart of a manufacturing method of an oxide semiconductor device 103 according to a third embodiment of the present invention. FIG. 15 is a schematic drawing illustrating the oxide semiconductor device 103 in this embodiment. As shown in FIG. 14 and FIG. 15, the oxide semiconductor transistor 20 is formed on the interposer substrate 10 in step S31; the capacitor structure 20C is formed on the interposer substrate 10 in step S32; the first interconnection 41 is then formed on the interposer substrate 10 in step S33; and the TSV 50 is formed in the interposer substrate 10 in step S34. The second interconnection 42 is formed on the interposer substrate 10 before the step of forming the oxide semiconductor transistor 20, and the first interconnection 41 is formed after the step of forming the oxide semiconductor transistor 20. The interconnection structure 40 and the oxide semiconductor transistor 20 are formed before the step of forming the TSV 50, and there is no stress and contamination concern for the oxide semiconductor transistor 20 in the process of forming the TSV 50. In addition, high temperature processes may also be applied before the step of forming the TSV 50 because the TSVs 50 are formed last relatively.

To summarize the above descriptions, in the oxide semiconductor device and the manufacturing method thereof in the present invention, the oxide semiconductor transistor is integrated with the interposer substrate having the TSV. The process sequence of the oxide semiconductor transistor, the TSV, and the interconnection structure is modified for different considerations. Additionally, the capacitor structure connected to the oxide semiconductor transistor is also integrated with the interposer substrate having the TSV for forming the oxide semiconductor memory cell with relatively longer data retention performance because of the ultra-low leakage current property of the oxide semiconductor transistors. The power consumption of the oxide semiconductor device will be relatively low and maybe applied to save power in the active modes and the standby modes.

Those skilled in the art will readily observe that numerous modifications and alterations of the device and method may be made while retaining the teachings of the invention. Accordingly, the above disclosure should be construed as limited only by the metes and bounds of the appended claims.

1. A manufacturing method of an oxide semiconductor device, comprising:
providing an interposer substrate;
forming at least one oxide semiconductor transistor on the interposer substrate;
forming at least one trough silicon via (TSV) in the interposer substrate; and
forming an interconnection structure on the interposer substrate, wherein the at least one oxide semiconductor transistor is connected to the interconnection structure.

2. The manufacturing method of claim 1, wherein the TSV is formed after the step of forming the oxide semiconductor transistor.

3. The manufacturing method of claim 2, wherein the interconnection structure is formed after the step of forming the TSV.

4. The manufacturing method of claim 2, wherein the interconnection structure is formed before the step of forming the TSV.

5. The manufacturing method of claim 4, wherein the interconnection structure comprises a first interconnection and a second interconnection, the second interconnection is formed before the step of forming the oxide semiconductor transistor, and the first interconnection is formed after the step of forming the oxide semiconductor transistor.

6. The manufacturing method of claim 1, wherein the TSV is formed before the step of forming the oxide semiconductor transistor.

7. The manufacturing method of claim 6, wherein the interconnection structure comprises a first interconnection and a second interconnection, the second interconnection is formed before the step of forming the oxide semiconductor transistor and after the step of forming the TSV, and the first interconnection is formed after the step of forming the oxide semiconductor transistor.

8. The manufacturing method of claim 1, further comprising:
forming a capacitor structure on the interposer substrate, wherein the capacitor structure is connected to the oxide semiconductor transistor for forming an oxide semiconductor memory cell.

9. The manufacturing method of claim 1, wherein the oxide semiconductor transistor is electrically connected to the TSV through the interconnection structure.

10. The manufacturing method of claim 1, further comprising:
attaching at least one die to the interconnection structure, wherein the oxide semiconductor transistor is electrically connected to the die through the TSV and/or the interconnection structure.

11. An oxide semiconductor device, comprising:
an interposer substrate;
at least one trough silicon via (TSV), wherein at least a part of the at least one TSV is disposed in the interposer substrate;
at least one oxide semiconductor transistor disposed on the interposer substrate;
a first interlayer dielectric disposed on the interposer substrate, wherein the oxide semiconductor transistor is disposed between the first interlayer dielectric and the interposer substrate;
an interconnection structure disposed on the first interlayer dielectric, wherein the at least one oxide semiconductor transistor is connected to the interconnection structure, and the TSV penetrates the interposer substrate and the first interlayer dielectric for being connected to the interconnection structure; and
a capacitor structure disposed on the interposer substrate, wherein the capacitor structure is connected to the oxide semiconductor transistor for forming an oxide semiconductor memory cell, and the capacitor structure comprises:
a first conductive pattern;
a dielectric pattern disposed on the first conductive pattern; and
a second conductive pattern disposed on the dielectric pattern; and
at least one capacitor trench disposed in the first interlayer dielectric, wherein at least a part of the capacitor structure is disposed in the capacitor trench, and the capacitor trench is filled with the first conductive pattern, the dielectric pattern, and the second conductive pattern, wherein from a top view of the capacitor structure, the shape of the capacitor trench comprises a cross.

12. The oxide semiconductor device of claim 11, wherein a memory array composed of a plurality of the oxide semiconductor memory cells is disposed on the interposer substrate.

13. (canceled)

14. The oxide semiconductor device of claim 11, wherein the first conductive pattern and the dielectric pattern are conformally disposed in the capacitor trench.

15. (canceled)

16. The oxide semiconductor device of claim 11, wherein the first interlayer dielectric comprises a first dielectric layer and a second dielectric layer disposed on the first dielectric layer, and the capacitor trench penetrates the first dielectric layer.

17. The oxide semiconductor device of claim 16, wherein the capacitor trench further penetrates the second dielectric layer.

18. The oxide semiconductor device of claim 11, wherein the oxide semiconductor transistor is electrically connected to the TSV through the interconnection structure.

19. The oxide semiconductor device of claim 11, further comprising:
at least one die disposed on the interconnection structure, wherein the oxide semiconductor transistor is electrically connected to the die through the TSV and/or the interconnection structure.
